(19) United States
(12) Patent Application Publication
(10) Pub. No.: US 2026/0033302 A1
(43) Pub. Date: Jan. 29, 2026

(54) MULTI-STEP ETCHING IN MEMORY ARCHITECTURES

(71) Applicant: Micron Technology, Inc., Boise, ID (US)

(72) Inventors: Richard J. Hill, Boise, ID (US); Lars P. Heineck, Boise, ID (US); Yoshiaki Fukuzumi, Yokohama (JP)

(21) Appl. No.: 19/272,889

(22) Filed: Jul. 17, 2025

Related U.S. Application Data
(60) Provisional application No. 63/676,830, filed on Jul. 29, 2024.

(51) Int. Cl. H01L 21/762; H10B 41/27; H10B 43/27

(52) U.S. Cl. CPC H01L 21/76224; H10B 41/27; H10B 43/27

(57) ABSTRACT

Methods, systems, and devices for multi-step etching in memory architectures are described. A semiconductor device may be formed based on multiple etching operations. A first set of cavities may be etched through one or more materials prior to formation of conductive materials in the semiconductor device. Each first cavity may be etched through at least a portion of a first channel and a second channel of a set of multiple channels of the semiconductor device. After a formation of the conductive materials, one or more second cavities may be etched through a portion of the first set of oxide filled cavities and a portion of the conductive materials. The one or more second cavities may complete a division of the semiconductor device into multiple subblocks.

### CROSS REFERENCE

The present Application for Patent claims priority to U.S. Patent Application No. 63/676,830 by Hill et al., entitled “MULTI-STEP ETCHING IN MEMORY ARCHITECTURES,” filed Jul. 29, 2024, which is assigned to the assignee hereof, and which is expressly incorporated by reference in its entirety herein.

### TECHNICAL FIELD

The following relates to one or more systems for memory, including multi-step etching in memory architectures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports multi-step etching in memory architectures in accordance with examples as disclosed herein.

FIG. 2 shows an example of a memory architecture that supports multi-step etching in memory architectures in accordance with examples as disclosed herein.

FIG. 3 shows an example of a semiconductor device that supports multi-step etching in memory architectures in accordance with examples as disclosed herein.

FIGS. 4 through 10 show example operations for forming a semiconductor device that supports multi-step etching in memory architectures in accordance with examples as disclosed herein.

FIG. 11 shows a flowchart illustrating a method or methods that support multi-step etching in memory architectures in accordance with examples as disclosed herein.

### DETAILED DESCRIPTION

As part of a manufacturing procedure, some semiconductor devices (e.g., such as not-AND (NAND) memory systems, three-dimensional (3D) NAND architectures) may be separated into various portions, which may be referred to as subblocks (e.g., as part of a select gate drain (SGD) formation procedure). In some cases, a “subblock” may refer to a portion of the semiconductor device that is at least partially isolated from other portions of the semiconductor device. For instance, a semiconductor device may include multiple subblocks that each include respective sets of memory channels (e.g., NAND channels, including one or more memory cells) that may be separately accessed based on the formation of the subblocks. In some cases, the semiconductor device may be divided into multiple subblocks based on an etching operation (e.g., a single cut) in which multiple materials of the semiconductor device may be removed simultaneously. However, such etching operations may cut through one or more of the memory channels and cause the memory channel to be unusable, thus reducing a storage capacity of the semiconductor device. Moreover, some etching operations may be performed after a formation of conductive materials (e.g., metal materials for word lines and other structures of the semiconductor device), and etching the conductive materials may produce debris particles (e.g., fragments of conductive material), which may adversely affect a performance of the device (e.g., by inhibiting a connection with the memory channels). Furthermore, performing etching operations to form sub-blocks before replacing nitride materials with conductive materials may prevent some nitride materials from being replaced.

In accordance with one or more techniques described herein, a semiconductor device may be formed based on multiple etching operations. In some examples, a first set of cavities (e.g., trenches) may be etched through one or more materials (e.g., oxide materials and nitride materials) prior to formation of conductive materials in the semiconductor device (e.g., prior to a replacement gate (RG) process). Each first cavity may be etched through (e.g., each cavity may extend through) at least a portion of a first channel (e.g., first NAND channel) and a second channel (e.g., second NAND channel). While the first cavity may be etched through at least a portion of a channel, the first etch may be positioned to ensure that the first channel and the second channel are configured as a NAND channel to store information in memory cells. The first set of cavities may be filled with an oxide material. After the first set of cavities are filled, one or more nitride materials of the semiconductor device may be replaced with one or more conductive materials (e.g., metal) to form word lines as part of an RG process. Each filled cavity (e.g., filled with the oxide material) of the first set of cavities may be separated from each other (e.g., spaced apart), which may allow for the one or more conductive materials to flow in between the filled cavities (e.g., as part of the RG process).

In some examples, after the formation of the word lines through the RG process, one or more second cavities (e.g., trenches) may be etched (e.g., and later filled with an oxide material) through a portion of the first set of oxide filled cavities and a portion of the conductive materials. The one or more second cavities may complete a division (e.g., an electrical division) of the semiconductor device (e.g., and the memory channels therein) into multiple subblocks. Thus, based on performing multiple etching and filling operations (e.g., both before and after an RG process) semiconductor devices may be manufactured without sacrificing memory channels, and debris deposited on the device as part of etching conductive materials may be reduced thereby causing increased reliability, among other benefits.

In addition to applicability in memory systems as described herein, techniques for multi-step etching in memory architectures may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing materials used in production of electronic devices, which may reduce electronic waste and extend the life of electronic devices (e.g., based on increased reliability of memory channels), among other benefits.

Features of the disclosure are illustrated and described in the context of systems and memory architectures. Features of the disclosure are further illustrated and described in the context of semiconductor devices, illustrative operations for semiconductor device formation, and flowcharts.

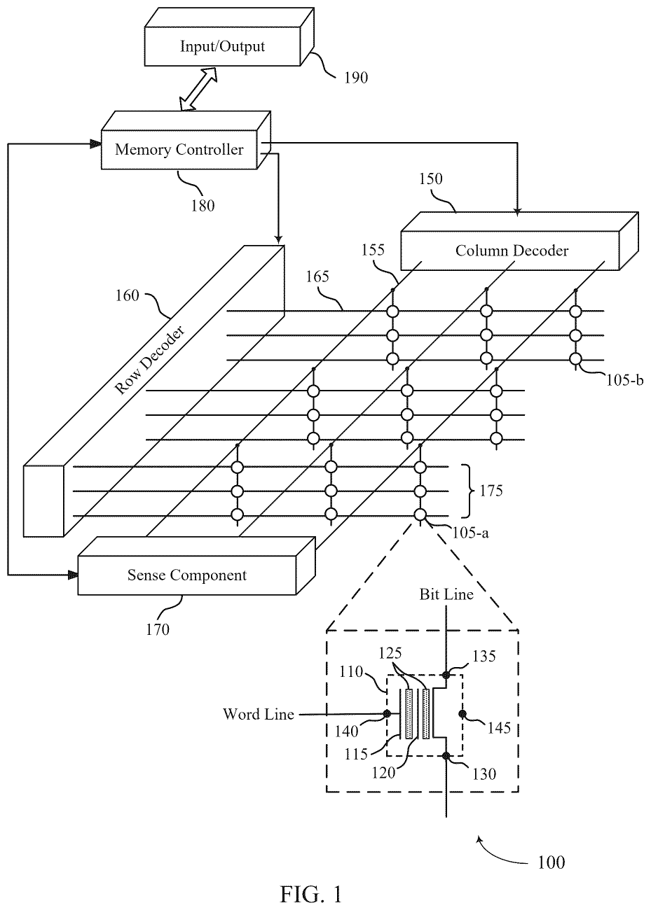

FIG. 1 shows an example of a memory device 100 that supports multi-step etching in memory architectures in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

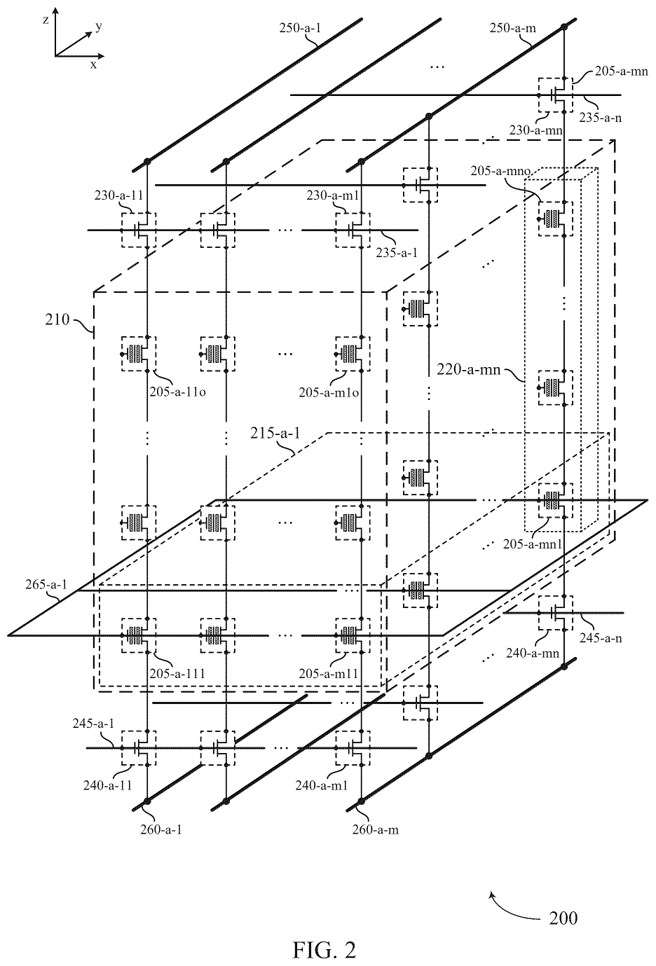

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

As part of a manufacturing procedure, some memory devices 100 may be separated into various portions known as subblocks. For instance, a memory device 100 may include multiple subblocks that each include respective sets of channels (e.g., memory cell stacks 175, access circuitry associated with multiple memory cells 105) that may be individually accessed based on the formation of the subblocks. However, some etching operations associated with forming the subblocks may cut through one or more of the channels, thus reducing a quantity of usable memory cells 105 at the memory device 100. Moreover, some etching operations may produce debris particles (e.g., metal fragments), which may adversely affect a performance of the memory device 100.

In accordance with one or more techniques described herein, a memory device 100 may be formed based on multiple etching operations. In some examples, a first set of cavities (e.g., trenches) may be etched through one or more materials (e.g., oxide materials and nitride materials) prior to formation of conductive materials (e.g., formation of the word lines 165) in the memory device 100 thereby reducing debris particles. In some examples, after the formation of the conductive materials (e.g., the word lines 165), one or more second cavities (e.g., trenches) may be etched (e.g., and later filled with an oxide material) through a portion of the first set of oxide filled cavities and a portion of the conductive materials. The one or more second cavities may complete a division of the memory device 100 (e.g., and the memory channels therein) into multiple subblocks. Thus, based on performing multiple etching and filling operations (e.g., both before and after an RG process) memory devices 100 may be manufactured without sacrificing memory channels and may have increased reliability, among other benefits.

FIG. 2 shows an example of a memory architecture 200 that supports multi-step etching in memory architectures in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

As part of a manufacturing procedure, some semiconductor devices including the memory architecture 200 may be separated into various portions known as subblocks (e.g., relatively smaller portions within a block 210). For instance, a semiconductor device including the memory architecture 200 may include multiple subblocks that each include respective sets of channels (e.g., access circuitry associated with multiple memory cells 205, a string 220) that may be accessed based on the formation of the subblocks. However, some etching operations associated with forming the subblocks may cut through one or more of the channels, thus reducing a quantity of usable memory cells 205 in the memory architecture 200. Moreover, some etching operations may produce debris particles (e.g., metal fragments), which may adversely affect a performance of the memory architecture 200.

In accordance with one or more techniques described herein, a semiconductor device including the memory architecture 200 may be formed based on multiple etching operations. In some examples, a first set of cavities (e.g., trenches) may be etched through one or more materials (e.g., oxide materials and nitride materials) prior to formation of conductive materials (e.g., formation of the word lines 265) in the semiconductor device thereby reducing debris particles. In some examples, after the formation of the conductive materials (e.g., the word lines 265), one or more second cavities (e.g., trenches) may be etched (e.g., and later filled with an oxide material) through a portion of the first set of oxide filled cavities and a portion of the conductive materials. The one or more second cavities may complete a division of the semiconductor devices including the memory architecture 200 (e.g., and the memory channels therein) into multiple subblocks. Thus, based on performing multiple etching and filling operations (e.g., both before and after an RG process) semiconductor devices that include the memory architecture 200 may be manufactured without sacrificing memory channels and may have increased reliability, among other benefits.

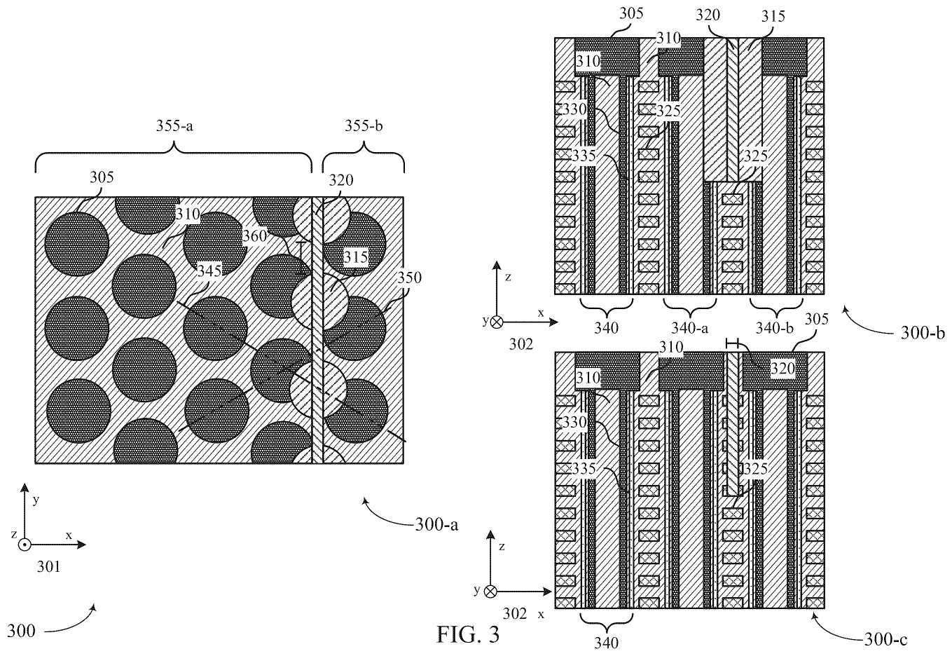

FIG. 3 shows an example of a semiconductor device 300 (e.g., a NAND memory system, a 3D NAND architectures, a 3D NAND device) that supports multi-step etching in memory architectures in accordance with examples as disclosed herein. The semiconductor device 300-a may be a top view of the device, which may be described with reference to an x-direction, a y-direction, and a z-direction of the coordinate system 301. The semiconductor device 300-b may be a cross-sectional view of the semiconductor device 300 along a line 345. The semiconductor device 300-c may be a cross-sectional view of the semiconductor device 300 along the line 350. The semiconductor device 300-a and the semiconductor device 300-b may be described with reference to an x-direction, a y-direction, and a z-direction of the coordinate system 302.

As part of a manufacturing process, the semiconductor device 300 may be separated into various subblocks 355 (e.g., as part of SGD formation). For instance, the semiconductor device 300 may include a subblock 355-a and a subblock 355-b (e.g., the subblock 355-b may not be fully shown for simplicity). Although the illustrative example of the semiconductor device 300 includes two subblocks, a semiconductor device may include any quantity of subblocks (e.g., two or more, four, eight, etc.). The subblock 355-a may be at least partially isolated from the subblock 355-b, which may enable individual access (e.g., addressing) of the subblock 355-a and the subblock 355-b respectively.

The subblock 355-a may include a first set of channels 340 (e.g., NAND channels, doped hollow channels (DHCs)) and the subblock 355-b may include a second set of channels 340 (e.g., NAND channels, DHCs). In some cases, a “channel” may refer to a pillar comprising a plurality of NAND memory cells. The channel may include a conductive material that acts as the bit line and other materials positioned between the bit line and a word line 325 that are configured to store charge and act as NAND memory cells. Thus, a memory cell may be formed between the conductive material of the channel 340 and the conductive material of the word lines 325 of the semiconductor device 300. In some cases, a “NAND channel” may refer to the materials of the channel 340 that are positioned between the conductive material acting as the bit line and the conductive material acting as the word line 325. Each channel 340 may be associated with multiple word lines 325, which may be formed of a conductive material. In the examples of the semiconductor device 300, each channel 340 may include a cylinder 335 formed of a nitride material and a cylinder 330 formed of a polysilicon material. The cylinder 330 may be surrounded by one or more oxide materials 310 and may be formed with the cylinder 335 (e.g., the cylinder 330 and the cylinder 335 may be concentric and separated by the oxide materials 310). The one or more oxide materials 310 may fill a portion of the channel 340. In some examples, a plug 305 may be formed of a polysilicon material and may terminate the channel 340 at one end (e.g., a top of the channel 340). Additionally, a channel 340 may itself be isolated from other channels 340 (e.g., surrounded) by one or more oxide materials 310 of the semiconductor device 300.

In some cases, the semiconductor device 300 may be divided into multiple subblocks 355 based on a single etching operation (e.g., a single cut) that removes multiple materials (e.g., oxide, polysilicon, metal) of the semiconductor device 300 simultaneously. However, such an etching operation may cut through one or more of the channels 340, thus rendering the cut channels 340 of the semiconductor device 300 unusable. Moreover, such an etching operation may be performed after a formation of conductive materials associated with the word lines 325 (e.g., copper or other metal material for the word lines 325 and other structures of the semiconductor device 300). Thus, and etching the conductive materials may produce debris particles (e.g., metal fragments), which may adversely affect a performance of the channels 340, as well as other contacts of the semiconductor device 300.

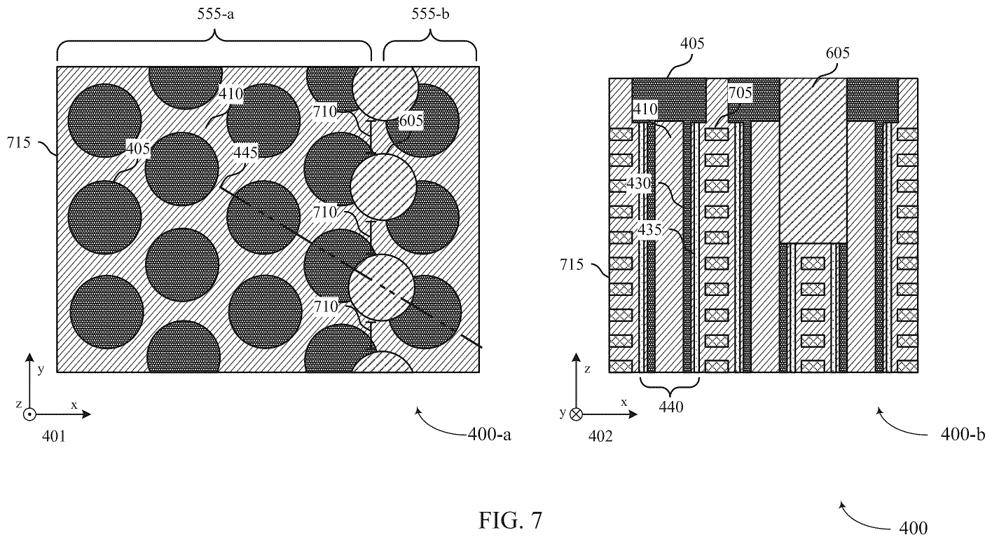

In accordance with one or more techniques described herein, a semiconductor device 300 may be formed based on multiple etching operations (e.g., a two-step SGD cut). In some examples, the multiple etching operations may enable a first etching operation (e.g., a cell and DHC cut) of a first set of cavities (e.g., trenches), which may be filled with an oxide material and form the oxide materials 315, and a second etching operation of one or more second cavities (e.g., trenches), which may be filled with an oxide material and form the oxide materials 320. The first cavities may be etched prior to an RG process (e.g., to enable cleaning and passivation flexibility, without oxidizing word line 325 metals) and may support access to inner subblocks 355 (e.g., inner SGD access, the subblock 355-b) of the semiconductor device 300 based on a gap 360 between each cavity. An “RG process” may refer to a replacement of one or more nitride materials (e.g., associated with the word lines 325, metal) with one or more conductive materials and is described in greater detail herein, including with reference to FIG. 7. Additionally, each first cavity may be formed through (e.g., extend through) at least a portion of a first channel 340 (e.g., channel 340-a) and a second channel 340 (e.g., channel 340-b).

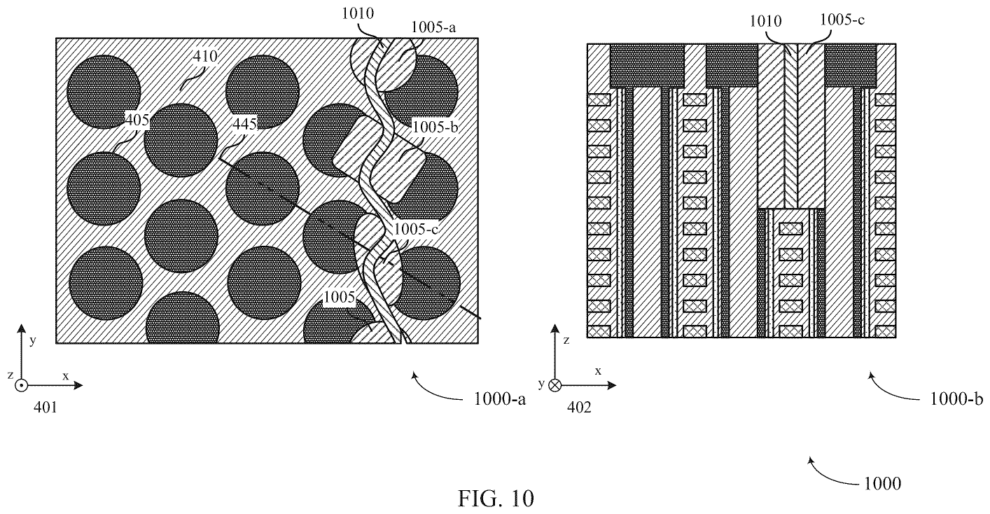

In some examples, the one or more second cavities may be etched after the RG process (e.g., and filled with an oxide material), which may complete a division of the semiconductor device 300 (e.g., and the multiple channels 340) into multiple subblocks 355. That is, the one or more oxide materials 320 may be formed through a portion of the first oxide materials 315, a portion of the one or more oxide materials 310, a portion of the word lines 325. The formation of the one or more oxide materials 320 may complete a division of the semiconductor device (e.g., and the memory channels therein) into multiple subblocks 355. In some examples, the oxide materials 315 may be formed using various geometries (e.g., different shapes), which may be described in greater detail herein, including with reference to FIG. 10. In some examples, the one or more oxide materials 320 may be formed based on a single second cavity (e.g., a continuous trench along the semiconductor device 300). Alternatively, the one or more oxide materials 320 may be formed based on multiple second cavities (e.g., discrete cuts made between the oxide materials 315 and along a boundary between subblocks 355, cuts made in each of the gaps 360).

Thus, based on the oxide materials 315 and the one or more oxide materials 320 the subblock 355-a and the subblock 355-b may be (e.g., at least at some portions) electrically isolated from each other. By applying the techniques described herein, the subblocks 355 may be formed without disabling one or more channels 340 of the semiconductor device 300. Moreover, a semiconductor device 300 may be manufactured with reduced cost and increased reliability. For example, the semiconductor device 300 may be associated with increased performance and increased gate control based on the multiple etching procedures (e.g., resulting in reduced particle debris and improved isolation of the channels 340), which may separately form the oxide materials 315 and the one or more oxide materials 320.

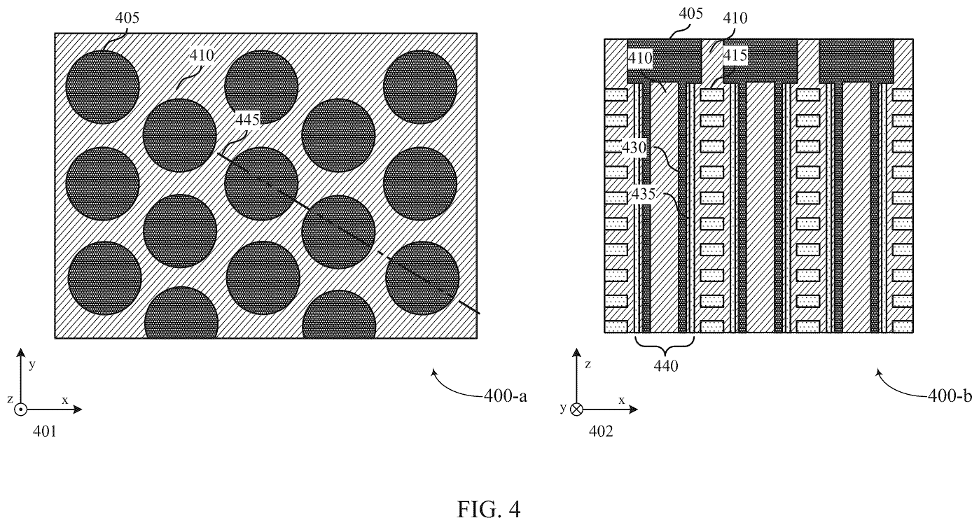

FIGS. 4 through 9 illustrate examples of operations for forming a semiconductor device 400 (e.g., a NAND device, a 3D NAND device) utilizing multi-step etching in memory architectures in accordance with examples as disclosed herein. For example, FIGS. 4 through 9 may illustrate aspects of a sequence of operations that may support manufacturing a memory device 100 or a portion thereof, a memory architecture 200 or a portion thereof, a semiconductor device 300, or some other device herein, which may reduce cost and improve device reliability. Each of the figures may be described with reference to an x-direction, a y-direction, and a z-direction of the coordinate system 401 or of the coordinate system 402. Operations illustrated in and described with reference to FIGS. 4 through 9 may be performed by a manufacturing system, such as a semiconductor fabrication system configured to perform additive operations (e.g., deposition, epitaxy, bonding, adhering), subtractive operations (e.g., etching, trenching, planarizing, polishing, dicing, cutting, separating), modifying operations (e.g., oxidizing, doping, reacting, converting), and supporting operations (e.g., masking, patterning, photolithography, aligning), among other operations that support the described techniques. In some examples, portions of the semiconductor device 400 that are illustrated with a same pattern may be formed of same or similar materials and portions that are illustrated with different patterns may be formed of different materials.

FIG. 4 shows an example of a semiconductor device 400 after a first set of one or more manufacturing operations. The semiconductor device 400-a may be a top view of the device, which may be described with reference to the coordinate system 401. The semiconductor device 400-b may be a cross-sectional view of the semiconductor device 400 along a line 445 and may be described with reference to the coordinate system 402.

In some examples, the first set of operations may include forming multiple channels 440 (e.g., which may be examples of channels 340 as described with reference to FIG. 3) and multiple structures 415, which may be separated by one or more oxide materials 410. In some examples, a channel 440 may correspond to a NAND channel, which may be associated with one or more memory cells (e.g., NAND memory cells) formed along each channel 440 (e.g., between the channel 440 and the structures 415).

Each channel 440 may include (e.g., be formed of) a cylinder 435 formed of a nitride material and a cylinder 430 formed of a polysilicon material. The cylinder 430 and the cylinder 435 may have respective outer diameters and inner diameters. For example, an outer diameter may be greater than an inner diameter, which may give a thickness to the cylinder 430 and the cylinder 435. The cylinder 430 and the cylinder 435 may also have respective inner cavities that are filled by other materials (e.g., the oxide materials 410). In some examples, the cylinder 430 may be surrounded by one or more oxide materials 410 and may be formed within the cylinder 435 (e.g., within an inner cavity of the cylinder 435 prior to being filled with the oxide materials 410). That is, an inner diameter of the cylinder 435 may be relatively larger than an outer diameter of the cylinder 430, and a gap between the inner diameter of the cylinder 435 and the outer diameter of the cylinder 430 may be filled with the one or more oxide materials 410. Each channel 440 may include a plug 405 formed of the polysilicon material at an end of the cylinder 435 and the cylinder 430. The structures 415 may be formed of one or more nitride materials, which may be replaced with one or more conductive materials at a later operation to form multiple word lines (e.g., word lines 325).

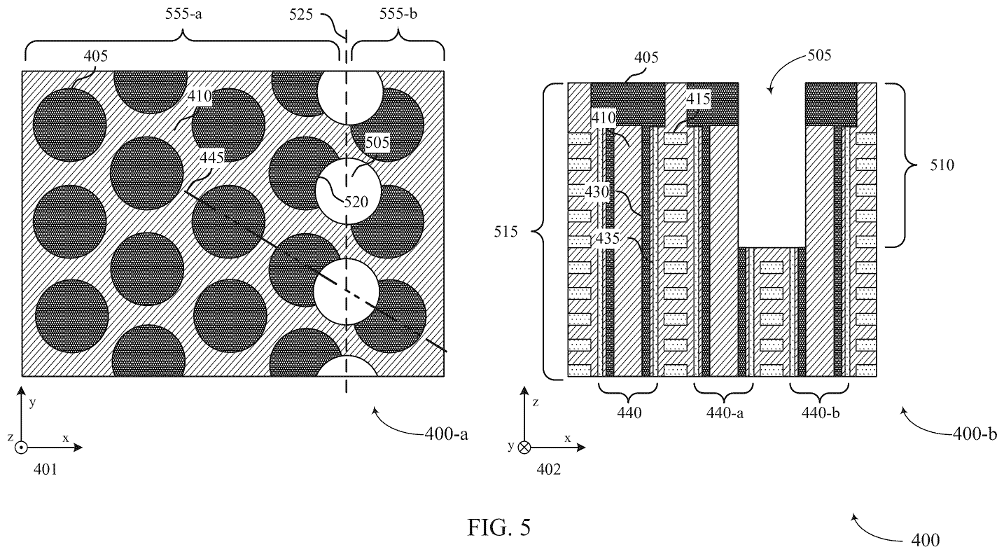

FIG. 5 shows an example of the semiconductor device 400 after a second set of one or more manufacturing operations. In some examples, the second set of operations may include etching (e.g., a first etch prior to an RG process) multiple first cavities 505 (e.g., trenches, holes) through a stack of materials of the semiconductor device 400. The stack of materials may include multiple layers of nitride materials (e.g., associated with the structures 415 and the cylinder 435 of the channel 440), oxide materials one or more oxide materials 410, and polysilicon materials (e.g., associated with the plug 405 and the cylinder 430). In some examples, each cavity 505 may extend (e.g., be etched) through at least a portion of a first channel 440-a and a second channel 440-b of the semiconductor device 400. While etching the first cavities 505 may remove at least a portion of the first channel 440-a and the second channel 440-b, the first etch may be performed (e.g., positioned) such that the first channel 440-a and the second channel 440-b may remain operable to store data in one or more memory cells associated with each channel. Thus, the second set of operations may mitigate a loss of storage capacity of the semiconductor device 400.

In some examples, the first cavities 505 may be etched at a depth 510 (e.g., along the z-directions), which may be less than a depth 515 (e.g., along the z-direction) associated with the channels 440. Although the depth 510 is shown as a non-limiting example, the first cavities 505 may be etched (e.g., via a dry etching process, a cell film cut) at any depth (e.g., based on a target quantity of source gate (SG) tiers) in the semiconductor device 400. The first cavities 505 may be etched along a boundary 525 between two or more subblocks 555 of the semiconductor device 400. In some examples, the first cavities 505 may expose a surface 520 (e.g., a sidewall) of the channel 440. The first set of operations may further include cleaning operations (e.g., to remove debris particles) and passivation operations.

A passivation operation (e.g., a DHC passivation, a high quality in situ steam generation (ISSG) option) may coat the first cavities 505 (e.g., and the surface 520, a DHC edge) with a protective layer and improve reliability of the channel 440. For example, the second set of operations may further include depositing, prior to depositing an oxide material in the cavities 505, a material (e.g., oxide, nitride, silicon, or other material) in the plurality of first cavities to insulate an exposed face (e.g., the surface 520) of each exposed channel (e.g., channel 440-a and channel 440-b) from the oxide material that will fill the cavities 505. Additionally, as the semiconductor device 400 may not include conductive materials at this manufacturing stage, the first cavities 505 may be etched without removing conductive materials (e.g., prior to and RG process).

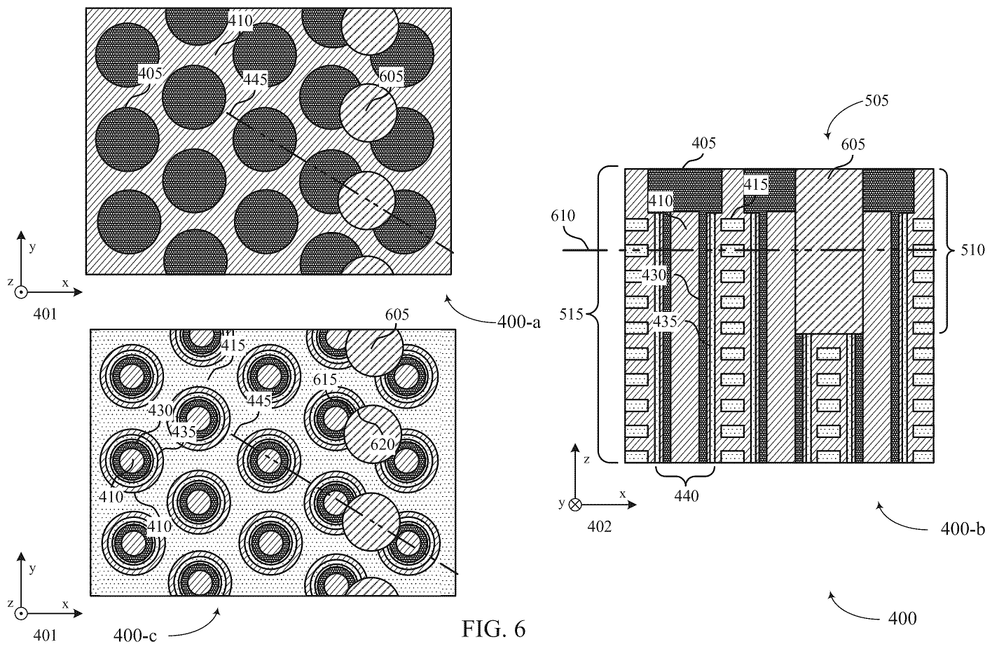

FIG. 6 shows an example of the semiconductor device 400 after a third set of one or more manufacturing operations. The semiconductor device 400-c may be a cross-sectional view of the semiconductor device 400 along a line 610 and may be described with reference to the coordinate system 401. In some examples, the third set of operations may include depositing (e.g., filling) an oxide material 605 in each of the first cavities 505 based on etching the first cavities 505, thus forming multiple oxide materials 605 (e.g., first oxide fills, first oxide portions, first oxide deposits). In some examples, the oxide materials 605 may be different than the oxide materials 410 (e.g., the surrounding oxide materials). The multiple oxide materials 605 may be formed at the depth 510 which may be less than the depth 515 associated with the channels 440.

In some examples, the third set of operation may further include one or more planarization operations (e.g., chemical mechanical planarization (CMP), polishing, grinding) in which a top surface of the semiconductor device 400 may be flattened (e.g., uniformly leveled). An edge 615 (e.g., a first DHC edge) of a cylinder 430 associated with a channel 440 and an edge 620 (e.g., a second DHC edge) of a cylinder 435 associated with a channel 440 may be terminated an edge of the multiple oxide materials 605. In some examples, the passivation operations (e.g., as described with reference to FIG. 5) may ensure that the edge 615 and the edge 620 are insulated such that leakages (e.g., electrical leakage, charge leakage) may be mitigated.

FIG. 7 shows an example of the semiconductor device 400 after a fourth set of one or more manufacturing operations. In some examples, the fourth set of operations may be an RG process associated with forming multiple word lines 705. That is, the fourth set of operations may include replacing, based on (e.g., after) depositing the oxide materials 605, one or more nitride materials associated with the structures 415 with a conductive material (e.g., a metal material such as copper or aluminum), which may form multiple word lines 705. The word lines 705 may be associated with the channels 440 of the semiconductor device 400. For example, the one or more nitride materials may be exhumed (e.g., removed, via wet etching) from the semiconductor device 400 leaving empty cavities (e.g., voids) in place of the structures 415. Subsequently, one or more conductive materials may be introduced (e.g., injected, formed) into the semiconductor device 400 and may fill the empty cavities to form the multiple word lines 705.

As discussed herein, the cavities 505 and the oxide materials 605 may be formed such that each respective oxide material 605 (e.g., each individual filled cavity 505) may be spaced apart by at least some oxide material 410. That is, there may be a gap 710 between each of the multiple oxide materials 605 (e.g., as well as the channels 440) through which conductive materials may pass (e.g., flow), which may allow a replacement of the nitride materials in both the subblock 555-a and the subblock 555-b. That is, the fourth set of operations may include replacing the nitride materials with the conductive material for at least two subblocks 55 of the semiconductor device 400 based on oxide materials 410 that remain between each cavity 505 (e.g., each oxide material 605) after etching the first cavities 505. In some examples, the RG process may be initiated at an edge (e.g., an edge 715) the semiconductor device 400, and the conductive material may be introduced at the edge and flow throughout the semiconductor device 400 from the edge.

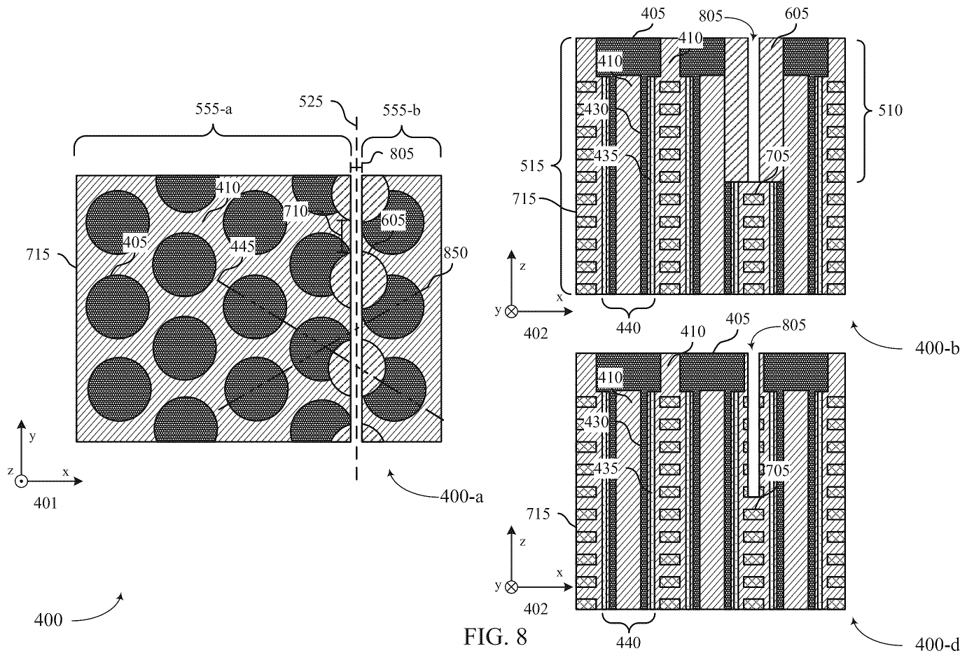

FIG. 8 shows an example of a semiconductor device 400 after a fifth set of one or more manufacturing operations. The semiconductor device 400-d may be a cross-sectional view of the semiconductor device 400 along a line 850 and may be described with reference to the coordinate system 402. In some examples, the fifth set of operations may include etching (e.g., a second etch), after replacing the nitride materials (e.g., as described with reference to FIG. 7), one or more second cavities 805 through at least a portion of the oxide materials 605 and a stack of materials including the conductive materials of at least some of the word lines 705 and a portion of one or more oxide materials 410 (e.g., alligator etching, etching of multiple materials at a same etch rate). In some examples, the one or more second cavities 805 may be etched along the boundary 525 between two or more subblocks 555 of the semiconductor device 400. That is, the etching of the one or more second cavities 805 may divide the channels 440 (e.g., the semiconductor device 400) into multiple subblocks 555. Each of the subblocks 555 (e.g., the subblock 555-a and the subblock 555-b) may be electrically isolated from each other based on etching (e.g., and filling) the first cavities 505 and etching (e.g., and filling) the one or more second cavities 805.

In some examples, the fifth set operation may include etching a single cavity 805 (e.g., a single cut through each of the multiple oxide materials 605, the one or more oxide materials 410, and the multiple word lines 705). In such examples, the cavity 805 may be etched according to different patterns, such as a weave between the plugs 405 (e.g., as described in greater detail herein, including with reference to FIG. 10). Additionally, a cavity 805 may be associated with a different width (e.g., different critical dimension, different etching parameter) along the semiconductor device 400. That is, the width of the cavity 805 may be relatively larger or relatively smaller at various portions along the semiconductor device 400. Alternatively, in some examples, the fifth set of operations may include etching a series of multiple second cavities 805 (e.g., discrete cavities, circular cavities, holes) in between each of the oxide materials 605 to divide the channels 440 into subblocks 555. Accordingly, the subblocks 555 may be electrically isolated from each other based on the series of multiple second cavities 805.

In some examples, the fifth set of operations may furth include depositing one or more oxide materials in the one or more second cavities 805 (e.g., the one or more oxide materials 320 as described with reference to FIG. 3). Accordingly, the first oxide materials 605 filling the first cavities 505 and the one or more second oxide materials filling the one or more second cavities 805 may be formed at a first depth 510 that is less than a second depth 515 associated with the channels 440. In some examples, the word lines 705 may be formed for multiple subblocks 555 based on etching the one or more second cavities 805 after the RG process. For instance, the RG process may be initiated from an edge 715 of the semiconductor device 400. If the one or more second cavities 805 were formed (e.g., and filled with an oxide material) prior to the RG process, the filled cavities 805 may prevent a conductive material to flow into (e.g., fill) the subblock 55-b. Thus, by performing the fifth set of operations after the RG process, multiple word lines 705 may be formed across various subblocks 555 of the semiconductor device 400.

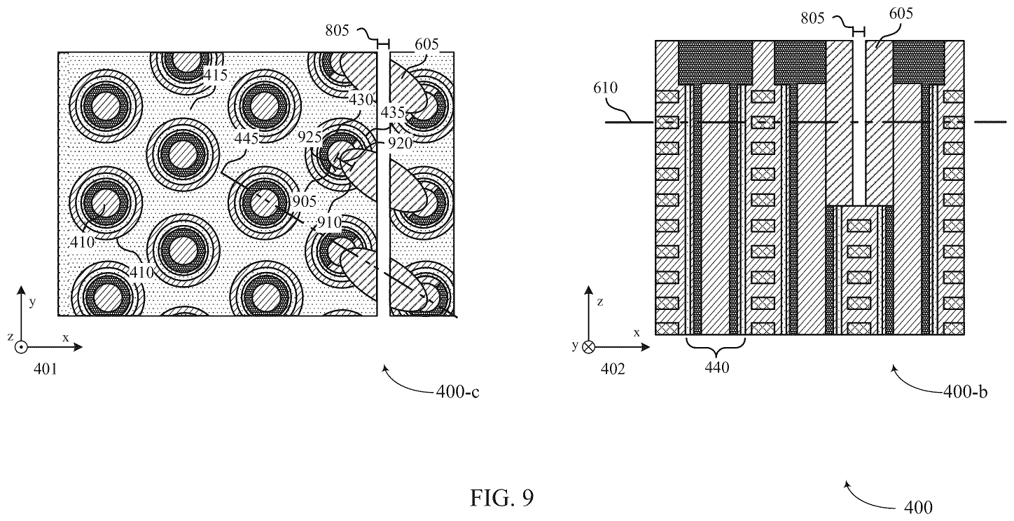

FIG. 9 shows an example of a semiconductor device 400 after a sixth set of one or more manufacturing operations, which may be performed additionally, alternatively, or not at all in conjunction with the techniques described herein. In some examples, the sixth set of operations may include removing (e.g., DHC recessing), for each channel 440, a portion of the cylinder 430 of the channel 440 (e.g., which may flatten an edge 905 of the cylinder 430). In some examples, the set of sixth operations may occur prior to depositing the oxide material 605 in the first cavities 505 (e.g., prior to the set of third operations described herein). That is, for a channel 440, an edge 910 of the cylinder 435 may extend beyond an edge 905 of the cylinder 430. In some examples, a gap 920 between the edge 905 and the edge 910 may be filled with an oxide material 925, which may be associated with (e.g., the same as) the oxide materials 605. In some examples, removing a portion of the cylinder 430 of the channel 440 may provide improved gate control and stability of the channel 440 by adjusting the electrical characteristics of the channel 440 (e.g., by reducing electric field interference between the edge 905 and the edge 910).

FIG. 10 shows an example of a semiconductor device 1000 that supports multi-step etching in memory architectures in accordance with examples as disclosed herein. The semiconductor device 1000-a may be a top view of the semiconductor device 1000, which may be described with reference to the coordinate system 401. The semiconductor device 1000-b may be a cross-sectional view of the semiconductor device 1000 along a line 445 and may be described with reference to the coordinate system 402.

The semiconductor device 1000 may be an alternate example of the semiconductor device 400 as described herein and may be formed utilizing one or more of the manufacturing operations in accordance with the operations described with reference to FIGS. 4 through 9. The example of the semiconductor device 1000 may illustrate various options of patterning for the first oxide materials 1005 (e.g., the first cavities 505, the multiple oxide materials 605) and the one or more second oxide materials 1010 (e.g., the one or more second cavities 805, the one or more oxide materials 320). For example, the first oxide materials 1005 may be formed as various geometric patterns (e.g., shapes), such as circle patterns (e.g., oxide material 1005-a), square patterns (e.g., oxide material 1005-b), oval patterns (e.g., oxide material 1005-c), oblong patterns, and so forth. Additionally, or alternatively, the one or more second oxide materials 1010 may be formed as a weave between (e.g., around, not through) the plugs 405 and through the first oxide materials 1005 and the one or more oxide materials 410.

In some examples, configurations using the various patterns for the first oxide materials 1005 and the one or more second oxide materials 1010 may improve (e.g., optimize) a performance of the semiconductor device 1000. For example, the various patterning may enhance a tolerance to variations in operating conditions, manufacturing inconsistencies, or other factors that may potentially impact a performance of the semiconductor device 1000. Accordingly, the techniques described herein may be utilized to further improve the reliability of a semiconductor device 1000 (e.g., a semiconductor device 400) under different operating conditions and to increase a yield of the manufacturing process, by making the semiconductor device 1000 relatively less susceptible to manufacturing inconsistencies.

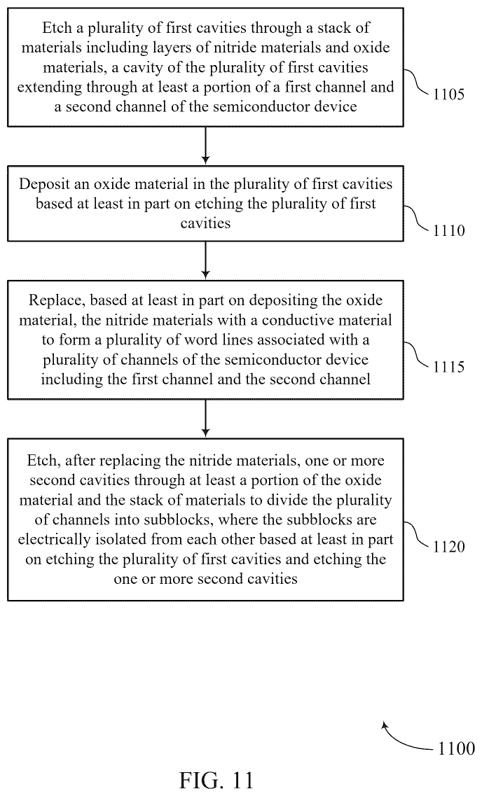

FIG. 11 shows a flowchart illustrating a method 1100 that supports multi-step etching in memory architectures in accordance with examples as disclosed herein. The operations of method 1100 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1105, the method may include etching a plurality of first cavities through a stack of materials including layers of nitride materials and oxide materials, a cavity of the plurality of first cavities extending through at least a portion of a first channel and a second channel of the semiconductor device.

At 1110, the method may include depositing an oxide material in the plurality of first cavities based at least in part on etching the plurality of first cavities.

At 1115, the method may include replacing, based at least in part on depositing the oxide material, the nitride materials with a conductive material to form a plurality of word lines associated with a plurality of channels of the semiconductor device including the first channel and the second channel.

At 1120, the method may include etching, after replacing the nitride materials, one or more second cavities through at least a portion of the oxide material and the stack of materials to divide the plurality of channels into subblocks, where the subblocks are electrically isolated from each other based at least in part on etching the plurality of first cavities and etching the one or more second cavities.

In some examples, an apparatus (e.g., a manufacturing system) as described herein may perform a method or methods, such as the method 1100. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for etching a plurality of first cavities through a stack of materials including layers of nitride materials and oxide materials, a cavity of the plurality of first cavities extending through at least a portion of a first channel and a second channel of the semiconductor device; depositing an oxide material in the plurality of first cavities based at least in part on etching the plurality of first cavities; replacing, based at least in part on depositing the oxide material, the nitride materials with a conductive material to form a plurality of word lines associated with a plurality of channels of the semiconductor device including the first channel and the second channel; and etching, after replacing the nitride materials, one or more second cavities through at least a portion of the oxide material and the stack of materials to divide the plurality of channels into subblocks, where the subblocks are electrically isolated from each other based at least in part on etching the plurality of first cavities and etching the one or more second cavities.

Aspect 2: The method or apparatus of aspect 1, where replacing the nitride materials includes operations, features, circuitry, logic, means, or instructions, or any combination thereof for replacing the nitride materials with the conductive material for at least two subblocks of the semiconductor device based at least in part on oxide materials that remain between each cavity of the plurality of first cavities after etching the plurality of first cavities.

Aspect 3: The method or apparatus of any of aspects 1 through 2, where each channel of the plurality of channels includes operations, features, circuitry, logic, means, or instructions, or any combination thereof for a first cylinder formed of a nitride material; a second cylinder formed of a polysilicon material, the second cylinder surrounded by the oxide materials and formed within a cavity of the first cylinder; and a plug formed of the polysilicon material at an end of the first cylinder and the second cylinder.

Aspect 4: The method or apparatus of aspect 3, where each channel of the plurality of channels is associated with a plurality of memory cells along each channel.

Aspect 5: The method or apparatus of any of aspects 3 through 4, further including operations, features, circuitry, logic, means, or instructions, or any combination thereof for removing, for each channel of the plurality of channels, a portion of the second cylinder prior to depositing the oxide material.

Aspect 6: The method or apparatus of any of aspects 1 through 5, further including operations, features, circuitry, logic, means, or instructions, or any combination thereof for depositing, prior to depositing the oxide material, a material in the plurality of first cavities to insulate an exposed face of each respective first channel and second channel from the oxide material.

Aspect 7: The method or apparatus of any of aspects 1 through 6, where etching the one or more second cavities includes operations, features, circuitry, logic, means, or instructions, or any combination thereof for etching a plurality of second cavities in between each of the plurality of first cavities to divide the plurality of channels, where the subblocks are electrically isolated from each other based at least in part on the plurality of second cavities.

Aspect 8: The method or apparatus of any of aspects 1 through 7, where the plurality of first cavities and the one or more second cavities are etched along a boundary between two or more subblocks of the semiconductor device.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A semiconductor device, including: a plurality of channels; a plurality of word lines associated with the plurality of channels; a plurality of first oxide materials, each first oxide material formed through at least a portion of a first channel and a second channel of the plurality of channels; and one or more second oxide materials formed through at least a portion of the plurality of first oxide materials and the plurality of word lines, where the one or more second oxide materials divide the plurality of channels into subblocks, the subblocks being electrically isolated from each other based at least in part on the plurality of first oxide materials and the one or more second oxide materials.

Aspect 10: The semiconductor device of aspect 9, where each channel of the plurality of channels includes: a first cylinder formed of a nitride material; a second cylinder formed of a polysilicon material, the second cylinder surrounded by an oxide material and formed within a cavity of the first cylinder; and a plug formed of the polysilicon material at an end of the first cylinder and the second cylinder.

Aspect 11: The semiconductor device of aspect 10, where, for the first channel and the second channel, a first edge of the first cylinder extends beyond a second edge of the second cylinder, a gap between the first edge and the second edge is filled with a second oxide material associated with the plurality of first oxide materials.

Aspect 12: The semiconductor device of any of aspects 9 through 11, where the plurality of first oxide materials and the one or more second oxide materials are formed at a first depth that is less than a second depth associated with the plurality of channels.

Aspect 13: The semiconductor device of any of aspects 9 through 12, where the one or more second oxide materials include: a plurality of second oxide materials in between each of the plurality of first oxide materials to divide the plurality of channels, where the subblocks are electrically isolated from each other based at least in part on the plurality of second oxide materials.

Aspect 14: The semiconductor device of any of aspects 9 through 13, where the plurality of first oxide materials and the one or more second oxide materials are formed along a boundary between two or more subblocks of the semiconductor device.

Aspect 15: The semiconductor device of any of aspects 9 through 14, where each channel of the plurality of channels is associated with a plurality of memory cells formed along each channel.

Aspect 16: The semiconductor device of any of aspects 9 through 15, where the plurality of channels corresponds to a plurality of NAND channels.

An apparatus is described. The following provides an overview of aspects of the apparatus as described herein:

Aspect 17: A product formed by a process of: etching a plurality of first cavities through a stack of materials including layers of nitride materials and oxide materials, a cavity of the plurality of first cavities extending through at least a portion of a first channel and a second channel of the product; depositing an oxide material in the plurality of first cavities based at least in part on etching the plurality of first cavities; replacing, based at least in part on depositing the oxide material, the nitride materials with a conductive material to form a plurality of word lines associated with a plurality of channels of the product including the first channel and the second channel; and etching, after replacing the nitride materials, one or more second cavities through at least a portion of the oxide material and the stack of materials to divide the plurality of channels into subblocks, where the subblocks are electrically isolated from each other based at least in part on etching the plurality of first cavities and etching the one or more second cavities.

Aspect 18: The product of aspect 17, where replacing the nitride materials includes: replacing the nitride materials with the conductive material for at least two subblocks of the product based at least in part on oxide materials that remain between each cavity of the plurality of first cavities after etching the plurality of first cavities.

Aspect 19: The product of any of aspects 17 through 18, the process further including: depositing, prior to depositing the oxide material, a material in the plurality of first cavities to insulate an exposed face of each respective first channel and second channel from the oxide material.

Aspect 20: The product of any of aspects 17 through 19, where etching the one or more second cavities includes: etching a plurality of second cavities in between each of the plurality of first cavities to divide the plurality of channels, where the subblocks are electrically isolated from each other based at least in part on the plurality of second cavities.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a plurality of channels;
a plurality of word lines associated with the plurality of channels;
a plurality of first oxide materials, each first oxide material formed through at least a portion of a first channel and a second channel of the plurality of channels; and
one or more second oxide materials formed through at least a portion of the plurality of first oxide materials and the plurality of word lines, wherein the one or more second oxide materials divide the plurality of channels into subblocks, the subblocks being electrically isolated from each other based at least in part on the plurality of first oxide materials and the one or more second oxide materials.

2. The semiconductor device of claim 1, wherein each channel of the plurality of channels comprises:
a first cylinder formed of a nitride material;
a second cylinder formed of a polysilicon material, the second cylinder surrounded by an oxide material and formed within the first cylinder; and
a plug formed of the polysilicon material at an end of the first cylinder and the second cylinder.

3. The semiconductor device of claim 2, wherein, for the first channel and the second channel, a first edge of the first cylinder extends beyond a second edge of the second cylinder, a gap between the first edge and the second edge is filled with a second oxide material associated with the plurality of first oxide materials.

4. The semiconductor device of claim 1, wherein the plurality of first oxide materials and the one or more second oxide materials are formed at a first depth that is less than a second depth associated with the plurality of channels.

5. The semiconductor device of claim 1, wherein the one or more second oxide materials comprise:
a plurality of second oxide materials in between each of the plurality of first oxide materials to divide the plurality of channels, wherein the subblocks are electrically isolated from each other based at least in part on the plurality of second oxide materials.

6. The semiconductor device of claim 1, wherein the plurality of first oxide materials and the one or more second oxide materials are formed along a boundary between two or more subblocks of the semiconductor device.

7. The semiconductor device of claim 1, wherein each channel of the plurality of channels is associated with a plurality of memory cells formed along each channel.

8. The semiconductor device of claim 1, wherein the plurality of channels corresponds to a plurality of not-AND (NAND) channels.

9. A method of manufacturing a semiconductor device, comprising:
etching a plurality of first cavities through a stack of materials comprising layers of nitride materials and oxide materials, a cavity of the plurality of first cavities extending through at least a portion of a first channel and a second channel of the semiconductor device;
depositing an oxide material in the plurality of first cavities based at least in part on etching the plurality of first cavities;
replacing, based at least in part on depositing the oxide material, the nitride materials with a conductive material to form a plurality of word lines associated with a plurality of channels of the semiconductor device including the first channel and the second channel; and
etching, after replacing the nitride materials, one or more second cavities through at least a portion of the oxide material and the stack of materials to divide the plurality of channels into subblocks, wherein the subblocks are electrically isolated from each other based at least in part on etching the plurality of first cavities and etching the one or more second cavities.

10. The method of claim 9, wherein replacing the nitride materials comprises:
replacing the nitride materials with the conductive material for at least two subblocks of the semiconductor device based at least in part on oxide materials that remain between each cavity of the plurality of first cavities after etching the plurality of first cavities.

11. The method of claim 9, wherein each channel of the plurality of channels comprises:
a first cylinder formed of a nitride material;
a second cylinder formed of a polysilicon material, the second cylinder surrounded by the oxide materials and formed within a cavity of the first cylinder; and
a plug formed of the polysilicon material at an end of the first cylinder and the second cylinder.

12. The method of claim 11, wherein each channel of the plurality of channels is associated with a plurality of memory cells along each channel.

13. The method of claim 11, further comprising:
removing, for each channel of the plurality of channels, a portion of the second cylinder prior to depositing the oxide material.

14. The method of claim 9, further comprising:
depositing, prior to depositing the oxide material, a material in the plurality of first cavities to insulate an exposed face of each respective first channel and second channel from the oxide material.

15. The method of claim 9, wherein etching the one or more second cavities comprises:
etching a plurality of second cavities in between each of the plurality of first cavities to divide the plurality of channels, wherein the subblocks are electrically isolated from each other based at least in part on the plurality of second cavities.

16. The method of claim 9, wherein the plurality of first cavities and the one or more second cavities are etched along a boundary between two or more subblocks of the semiconductor device.

17. A product formed by a process of:
etching a plurality of first cavities through a stack of materials comprising layers of nitride materials and oxide materials, a cavity of the plurality of first cavities extending through at least a portion of a first channel and a second channel of the product;
depositing an oxide material in the plurality of first cavities based at least in part on etching the plurality of first cavities;
replacing, based at least in part on depositing the oxide material, the nitride materials with a conductive material to form a plurality of word lines associated with a plurality of channels of the product including the first channel and the second channel; and
etching, after replacing the nitride materials, one or more second cavities through at least a portion of the oxide material and the stack of materials to divide the plurality of channels into subblocks, wherein the subblocks are electrically isolated from each other based at least in part on etching the plurality of first cavities and etching the one or more second cavities.

18. The product of claim 17, wherein replacing the nitride materials comprises:
replacing the nitride materials with the conductive material for at least two subblocks of the product based at least in part on oxide materials that remain between each cavity of the plurality of first cavities after etching the plurality of first cavities.

19. The product of claim 17, the process further comprising:
depositing, prior to depositing the oxide material, a material in the plurality of first cavities to insulate an exposed face of each respective first channel and second channel from the oxide material.

20. The product of claim 17, wherein etching the one or more second cavities comprises:
etching a plurality of second cavities in between each of the plurality of first cavities to divide the plurality of channels, wherein the subblocks are electrically isolated from each other based at least in part on the plurality of second cavities.
